(19) United States
(12) Patent Application Publication
(10) Pub. No.: US 2007/0202640 A1
(43) Pub. Date: Aug. 30, 2007

(54) Low-k spacer integration into CMOS transistors

(75) Inventors: Amir Al-Bayati, San Jose, CA (US); Reza Arghavani, Scotts Valley, CA (US); Mei-Yee Shek, Mountain View, CA (US); Li-Qun Xia, Santa Clara, CA (US); Mihaela Balseanu, Sunnyvale, CA (US); Bok Hoen Kim, San Jose, CA (US); Michael S. Cox, Davenport, CA (US); Chad Peterson, San Jose, CA (US); Hichem M'Saad, Santa Clara, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/365,740

(22) Filed: Feb. 28, 2006

(51) Int. Cl. H01L 21/338

(52) U.S. Cl. 438/184

(57) ABSTRACT

A method of forming source and drain regions in a semiconductor transistor. The method includes the steps of forming a first sidewall spacer on sidewall surfaces of a gate electrode that is formed on an underlying substrate, where the first sidewall spacer includes amorphous carbon. The method may also include implanting the source and drain regions in the semiconductor substrate, and removing the first sidewall spacer before annealing the source and drain regions. The method may still further include forming a second sidewall spacer on the sidewall surfaces of the gate electrode, where the second sidewall spacer has a k-value less than 4. Also, a method to enhance conformality of a sidewall spacer layer. The method may include the steps of pulsing a radio-frequency power source to generate periodically a plasma, and depositing the plasma on sidewall surfaces of a gate electrode to form the sidewall spacer layer.

### BACKGROUND OF THE INVENTION

Integrated circuit fabrication methods have reached a point where 50 to 100 million transistors or more are routinely formed on a single chip. Each new generation of fabrication techniques and equipment are allowing commercial scale fabrication of ever smaller and faster transistors, but also increase the difficulty to make even smaller, faster circuit elements. The shrinking dimensions of circuit elements, now well below the 100 nm threshold, has caused chip designers to look for new low-resistivity conductive materials and new low-dielectric constant (i.e., low-k) insulating materials just improve (and sometimes just to maintain) the electrical performance of the integrated circuit.

One increasing challenge to making smaller circuit elements is that as the elements get smaller, parasitic capacitance becomes an increasing impediment to good electrical performance. As FIG. 1 shows, three components of parasitic capacitance associated with the gate electrode of a transistor include gate to channel capacitance 102, overlap Miller capacitance 104, and fringe capacitance 106. The last type of parasitic capacitance, the fringe capacitance 106 between the gate electrode and sidewall spacer layers, typically makes the smallest contribution of the three. However, as the sizes of the transistors have been miniaturized to sub-90 nm dimensions (e.g., 65 nm fabrication is commercially feasible) the fringe capacitance from conventional sidewall spacer materials has grown relative to other types of gate electrode parasitic capacitance.

As shown in the graph of FIG. 2, fringe capacitance is growing almost exponentially as a percentage of the total gate capacitance as the transistor dimensions shrink to less than 90 nm. Thus, there is a need for new techniques and materials to form low-k sidewall spacers on the sides of the gate electrode that can reduce fringe capacitance as transistors get smaller. One possibility is to make sidewall spacers out of oxidized organo-silane films, such as the Black Diamond® films commercially available from Applied Materials, Inc. of Santa Clara, Calif. These films have lower dielectric constants (e.g., about 3.5 or less) than conventional spacer materials like silicon oxides and nitrides. Unfortunately, these carbon-silicon-oxide films tend to become much more conductive when exposed to temperatures (e.g., about 1000° C. or more) commonly used to anneal the source-drain and implant regions of a semiconductor transistor. Thus, there is a need for new transistor fabrication techniques that allow the incorporation of low-k materials into the sidewall spacers of semiconductor transistors.

Another problem with substituting lower-k carbon-silicon-oxide materials for more conventional sidewall spacer materials is the reduced conformality seen in the deposition of these films. Sidewall spacer depositions present conformality challenges not present with planar depositions on flat substrates. The gate electrode is normally joined perpendicularly to the semiconductor substrate, making a high % conformality of the sidewall spacer difficult to achieve around the right angle junction of these elements. The properties of carbon-silicon-oxide films make highly conformal depositions on the gate electrode sidewalls even more challenging. Thus there is a need for new sidewall spacer formation techniques that can improve the conformality of the spacer layers formed. These and other issues are addressed by the methods and systems of the present invention.

### BRIEF SUMMARY OF THE INVENTION

Embodiments of the invention include methods of forming source and drain regions in a semiconductor transistor. The methods may include the step of forming a first sidewall spacer on sidewall surfaces of a gate electrode that is formed on an underlying substrate, where the first sidewall spacer comprises amorphous carbon. The methods may also include implanting the source and drain regions in the semiconductor substrate, and removing the first sidewall spacer before annealing the source and drain regions. The methods may further include forming a second sidewall spacer on the sidewall surfaces of the gate electrode, where the second sidewall spacer has a k-value less than 4.

Embodiments of the invention may also include methods of forming implant regions in a semiconductor transistor. The methods may include the steps of forming source and drain regions adjacent to a gate electrode in a semiconductor substrate, and removing a first sidewall spacer from the gate electrode before annealing the source and drain regions, where the first sidewall spacer comprises amorphous carbon. The methods may still further include forming the implant regions in the semiconductor substrate, and forming a second sidewall spacer on sidewall surfaces of the gate electrode.

Embodiments of the invention may still also include methods of forming a semiconductor transistor. The methods may include the steps of forming a gate electrode on a semiconductor substrate, and forming a temporary sidewall spacer on sidewall surfaces of the gate electrode, where the temporary sidewall spacer comprises amorphous carbon. The methods may further include implanting source and drain regions in the semiconductor substrate, and removing the temporary sidewall spacer before annealing the source and drain regions, and forming a permanent low-k sidewall spacer on the sidewall surfaces of the gate electrode, where the low-k sidewall spacer comprises carbon-doped silicon oxide.

Embodiments of the invention may also include methods of forming a sidewall spacer. The methods may include the step of generating a plasma from one or more precursors comprising silicon, carbon, and oxygen, where the plasma is generated using low-frequency radio-frequency power. The methods may also include depositing the plasma on sidewall surfaces of a gate electrode to form a first portion of the sidewall spacer, pausing the deposition of the plasma on the sidewall surfaces of the gate electrode, and resuming the deposition of the plasma to form a second portion of the sidewall spacer.

Embodiments of the invention may also further include methods to enhance conformality of a sidewall spacer layer formed on a gate electrode. The methods may include the steps of pulsing a radio-frequency power source to generate periodically a plasma from one or more precursors comprising silicon, carbon, and oxygen, and depositing the plasma on sidewall surfaces of a gate electrode to form the sidewall spacer layer.

Embodiments of the invention may still also include methods of forming a conformal layer on a gate electrode. The methods may include generating a plasma from one or more precursors comprising silicon, carbon, and oxygen, where the plasma is generated with radio-frequency power consisting of low-frequency radio-frequency power. The methods may also include depositing the plasma on sidewall surfaces of a gate electrode to form the conformal layer.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

FIG. 1 shows a cross-section of a portion of a semiconductor transistor highlighting sources of gate capacitance in the transistor;

FIG. 2 shows a graph of the relative contribution of fringe capacitance to the total gate capacitance as the size of the transistor shrinks;

FIG. 3 is a flowchart illustrating steps in methods of making a transistor according to embodiments of the invention;

FIG. 4 is a flowchart illustrating methods of making low-k sidewall spacers according to embodiments of the invention;

FIGS. 5A-E show cross-sectional views of steps in forming source-drain regions in a transistor with the aid of a disposable sidewall spacer according to embodiments of the invention;

FIGS. 6A-E show cross-sectional views of steps in forming implant regions in a transistor according to embodiments of the invention;

FIGS. 7A-D show cross-sectional views of steps in forming sidewall spacers and silicide layers in a transistor according to embodiments of the invention;

FIG. 8A shows a vertical, cross-sectional view of an embodiment of an apparatus for PECVD in which the methods of the present invention may be carried out;

FIG. 8B shows a diagram of an embodiment of a system monitor an apparatus for PECVD that may be used with the methods of the present invention; and

FIG. 8C shows a block diagram of an embodiment of a hierarchical control structure, including system control software used with the apparatus for PECVD.

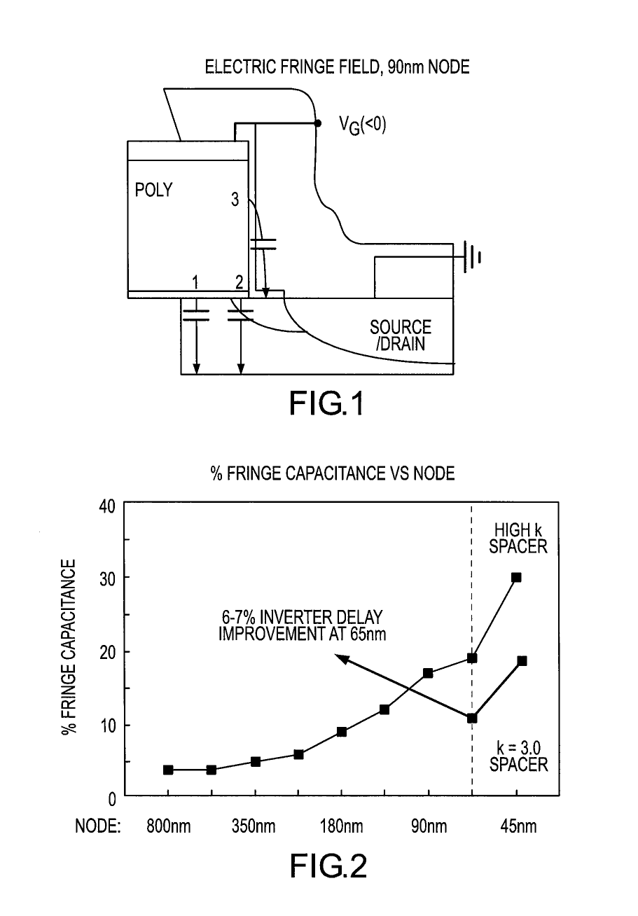

### DETAILED DESCRIPTION OF THE INVENTION

Overview

Systems and methods are described for forming conformal sidewall spacers that reduce the amount of fringe capacitance between the gate electrode and source/drain regions compared to conventional sidewall spacers with higher dielectric constants (i.e., k values). The methods include methods of forming low-k, carbon and silicon containing sidewall spacers after the formation and removal of a sacrificial spacer during the formation and high-temperature anneals (e.g., greater than 1000° C.) of the source/drain and other dopant regions, like halo regions, dopant extension regions, etc. The sacrificial spacer avoid the problem of the low-k spacer materials becoming conductive at high temperatures.

Also described are method of forming low-k spacers with improved conformality. Depositions of silicon and carbon containing spacer films often have reduced conformality when formed with conventional spacer deposition techniques (e.g., plasma deposition techniques for deposition silicon oxide and silicon-nitride films). Embodiments of the invention include the use of low-frequency radio frequency power to generate plasmas for depositions of the silicon and carbon containing low-k spacer layers. The use of LF-RF for plasma generation can improve the side-to-top conformality of the spacer layer by about 10% or more.

Embodiments of the invention also include pulsed-plasma deposition of the low-k spacer to further improve conformality. In pulsed-plasma deposition, the plasma is formed for a fraction of the deposition cycle and then paused for the remainder of the cycle. A typical duty cycle for the pulsed-plasma is about 10% to about 20% of each cycle. For example, a signal to turn on and off the power supply for the RF generator may be configured as a wave function that turns on the power supply for about 1 second followed by a off period of about 5 seconds. Pulsed-plasma deposition of the low-k spacer can also improve the side-to-top conformality of the spacer layer by about 10% or more.

Exemplary Methods

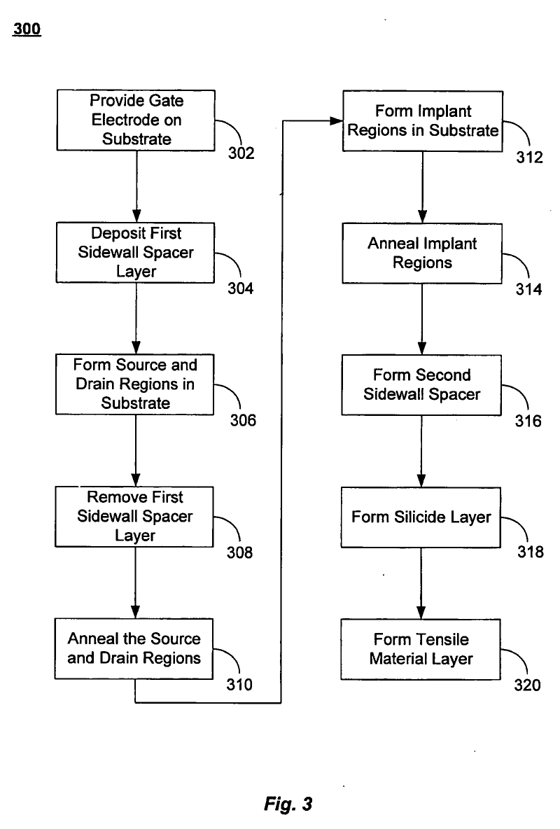

Referring now to FIG. 3 a flowchart illustrating steps in method 300 of making a transistor according to embodiments of the invention is shown. Method 300 may include providing a substrate upon which a gate electrode has been formed 302 and depositing a first sidewall spacer layer 304 on side surfaces of the gate electrode (e.g., surfaces oriented substantially perpendicular to a top surface of the substrate upon which the gate electrode is formed.) The sidewall spacer layer may cover the side surfaces of the gate electrode as well as a portion of the top surface of the substrate.

The first sidewall spacer layer may be made, at least in part, from amorphous carbon (e.g., α-carbon), such as the amorphous carbon found in the Advanced Patterning Film™ (“APF”) from Applied Materials of Santa Clara, Calif. The deposition of an amorphous carbon sidewall spacer layer may include providing a precursor mixture (e.g., a gas mixture) of a hydrocarbon compound and, in some instances, an inert gas such as argon (Ar) or helium (He) to the processing chamber containing the substrate. The hydrocarbon compound may be a saturated or unsaturated hydrocarbon having the formula CₓH_{y}, where x has a range of between 1 and 4, and y has a range between about 2 and 10. For example, the hydrocarbon compound may be methane (CH₄), ethane (C₂H₆), ethylene (C₂H₄), acetylene (C₂H₂), propane (C₃H₈), propylene (C₃H₆), propyne (C₃H₄), butane (C₄H₁₀), butylene (C₄H₈), butadiene (C₄H₆), as well as combinations of hydrocarbons among other compounds. The hydrocarbon may also include partially or completely halogenated derivatives of unsubstituted hydrocarbons (e.g., fluorinated derivatives such as C₃F₈ or C₄F₈). Additional gases may also be included in the precursor mixture, such as hydrogen (H₂), nitrogen (N₂) and/or ammonia (NH₃) to modify the properties of the amorphous carbon material. Argon, helium and/or nitrogen may be used to control the density and deposition rate of an amorphous carbon sidewall spacer layer. Additional description of materials that may be used in the precursor mixture can be found in co-assigned U.S. Pat. No. 6,541,397, issued Apr. 1, 2003, and titled “REMOVABLE AMORPHOUS CARBON CMP STOP”, the entire contents of which is herein incorporated by reference for all purposes.

The amorphous carbon layer may be formed on the sidewalls of the gate electrode though a plasma deposition process. The deposition process may include heating the substrate from about 100° C. to about 500° C. and flowing the amorphous carbon precursors into the chamber. The hydrocarbon precursor may flow into the chamber at a flow rate of about 50 sccm and 500 sccm, and the chamber pressure is typically maintained from about 1 Torr to about 20 Torr. The plasma may be generated by applying a RF power of about 3 W/cm² to about 20 W/cm² (e.g., about 1000 W to about 6000 W for a 200 mm substrate wafer). The precursor manifold for delivering the precursor materials into the chamber may be positioned about 300 mils to about 600 mils from the substrate surface.

The above process parameters provide a typical deposition rate for the amorphous carbon from about 100 Å/min to about 1000 Å/min, and may be implemented on a commercially available PECVD chamber such as the PRODUCER® chamber from Applied Materials of Santa Clara, Calif. The applied RF power and flow rates may be varied based on the substrate size and equipment used. For example, the RF power may be from 19 W/cm² to about 130 W/cm². It should be appreciated that the amorphous carbon deposition values and process parameters provided herein are illustrative, and should not be construed as limiting the methods and systems for forming an amorphous carbon sidewall spacer layer on the side surfaces of the gate electrode.

Following the deposition of the first sidewall spacer layers, the source and drain regions of the transistor may be formed in the substrate 306. The source and drain regions may be formed using conventional ion implantation. For example, ions (e.g., silicon ions, germanium ions, etc.) may be accelerated at about 5 keV to about 130 keV into the single crystal substrate 102 to form amorphous silicon implant regions. Accompanying the bombardment ions are dopants that are typically delivered in a dose of about 10¹⁵ ions/cm² (e.g., about 1×10¹³ to about 1×10¹⁵ ions/cm²). The dopants may be any dopant appropriate for the semiconductor device being manufactured, such as phosphorous, arsenic, etc. for an NMOS device, and boron, indium, etc. for a PMOS device.

The first sidewall spacer layer may be removed 308 after the formation of the source/drain region 306. When the first sidewall spacer layer is made from amorphous carbon (e.g., α-carbon) the spacer may be removed using a standard stripping or oxidative ashing process (e.g., a plasma based O₂ ashing process). Removal may also be done by subjecting the spacer to plasma of hydrogen-containing (H₂) gas. After the removal of the first sidewall spacer 308, the source and drain regions may be annealed 310 to activate the dopants in these regions. The anneal process may include a soak anneal where the whole transistor is heated to a temperature of greater than about 1000° C. (e.g., about 1050° C.). The annealing process may also include spike annealing or laser annealing to raise the temperature of the source and drain regions in a more localized fashion. Annealing processes that include a combination of soak, spike, and/or laser annealing may also be done to anneal the source and drain regions.

Before or after annealing the source and drain regions 310, implants (e.g., halo implants) may be formed in the substrate 312. The implant regions may also be formed via ion implantation. For example, dopant ions in concentrations of about 1×10¹² to about 1×10¹⁴ ions/cm² may be accelerated into substrate with implant energy of about 1 keV to about 20 keV to form the implant regions. After ion implantation, the implant regions may undergo one or more annealing 314 to position the dopants. For example, the device may be annealed at a temperature of about 900° C. to about 1100° C. In another example, the device may undergo rapid thermal annealing (RTA). Embodiments also include combining the anneal of the source and drain regions 310 and anneal of the implant regions 314 into a single anneal process that is done following the formation of the source/drain, and implant regions.

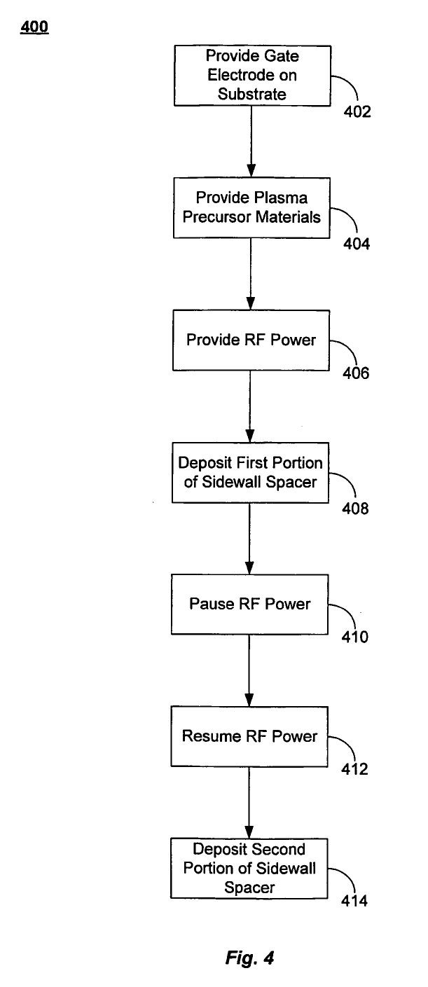

After the formation and annealing of the source/drain and implant regions, a second sidewall spacer may be formed on the side surfaces of the gate electrode 316. The second sidewall spacer layer may be formed from organosilane materials that impart a low dielectric constant to the spacer layer. Details about processes to form the second sidewall spacer layer with a high degree of conformality will be described below with reference to FIG. 4.

Following the formation of the permanent, second sidewall spacer layer 316, a silicide layer may be formed on the transistor 318. The silicide layers are conductive, and may be alloys of metal (e.g. Ti, Co, Ni, etc.) and silicon formed from the reaction of a metal layer with the underlying source-drain regions and gate electrode. In post-silicidation steps, electrical contacts may be formed on silicide layers to conduct electrical signals to and from the transistor. Additional details about the formation of silicide layers are described in co-assigned U.S. patent application Ser. No. 10/854,013, filed May 25, 2004, titled “METHOD FOR FORMING A LOW THERMAL BUDGET SPACER,” the entire contents of which is herein incorporated by reference for all purposes.

Additional layers may be formed over the silicide layers, such as a tensile film 320. The tensile film may be added to change or magnify the stress level in the channel region of the transistor to promote faster channel conductance. Additional details on the formation of tensile films that effect electron/ion conductance in the channel region of a transistor may be found in co-assigned U.S. patent application Ser. No. 10/846,734, filed May 14, 2004, titled “METHOD OF INDUCING STRESSES IN THE CHANNEL REGION OF A TRANSISTOR,” the entire contents of which is herein incorporated by reference for all purposes.

Referring now to FIG. 4, a flowchart illustrating methods 400 of forming low-k sidewall spacers according to embodiments of the invention. The method 400 may include providing a gate electrode on a substrate 402 to a plasma processing chamber. Plasma precursor materials 404 may also be provided to the processing chamber for a deposition of materials on the side surfaces of the gate electrode (e.g., Plasma-enhanced chemical vapor deposition “PECVD”). As the plasma precursors are being provided 404 to the chamber, radio frequency power may also be provided 406 to generate a plasma for the precursor materials. The RF power may be a combination of high-frequency RF and low-frequency RF, which has been found to improve the conformality of the spacer layer deposited with the plasma.

With the precursor materials flowing and the RF power turned on, the plasma that is formed may deposit a first portion of the sidewall spacer 408 on the side surfaces of the gate electrode, and an adjoining portion of the top surface of the substrate. A pause in the RF power 410 supplied to the processing chamber marks the end of the deposition of the first portion of the spacer. After a predetermined period, the supply of RF power to the chamber may resume 412, causing more plasma to be generated and deposited as a second portion of the sidewall spacer 414.

The pause and resumption of the RF power to the processing chamber may continue for several more cycles to complete the formation of the spacer. It has been discovered that pausing and resuming the plasma deposition (i.e., pulsed plasma deposition) can improve the conformality of an Si—O—C spacer layer by about 10% or more. For example, a pulsed plasma deposition that activates the RF power for less than about 20% of a duty cycle (e.g., the RF power is activated for 1 second, and then deactivated for 5 seconds) can improve the conformality of the deposited sidewall spacer from 50% for a continuously deposited plasma, to 60% or more for the pulsed plasma.

In one more specific example, the formation of a Si—O—C spacer layer may include flowing a precursor mixture of helium (e.g., 500 sccm) and octamethylcyclotetrasiloxane (OMCTS) (e.g., 750 mgm) through a precursor distribution manifold of the process chamber (e.g., positioning the substrate wafer about 500 mils from the manifold) to maintain a chamber pressure at about 6 Torr. The RF power may be a combination of high and low-frequency RF. For example, in a 200 mm wafer deposition the RF power may include about 250 Watts of HF-RF and about 50 Watts of LF-RF (e.g., 350 kHz) to make the total RF power about 300 Watts. The amount of HF and LF power may be roughly doubled for a 300 mm wafer deposition. The RF power may be periodically supplied to the chamber (e.g., 1 second on, 5 seconds off) to deposit consecutive portions of the spacer layer on the transistor. With this duty cycle and a continuous plasma deposition rate of about 1000 to 3000 Å/minute (e.g., 2000 Å/minute), each cycle of the pulsed plasma deposits about 10 Å to about 50 Å (e.g., about 33 Å) thick portion of the spacer layer. Typical thicknesses for the completed spacer layer are about 500 Å or more (e.g., about 500 Å to about 700 Å).

Pulsed plasma deposition has been observed to improve the conformality of amorphous carbon spacers, as well as Si—O—C spacers. Thus, when a transistor fabrication process uses a sacrificial sidewall spacer like in the methods described in FIG. 3, the pulsed plasma deposition may be used for depositing a temporary first spacer layer made from amorphous carbon, and a permanent second spacer layer made from Si—O—C containing materials.

Exemplary Transistors

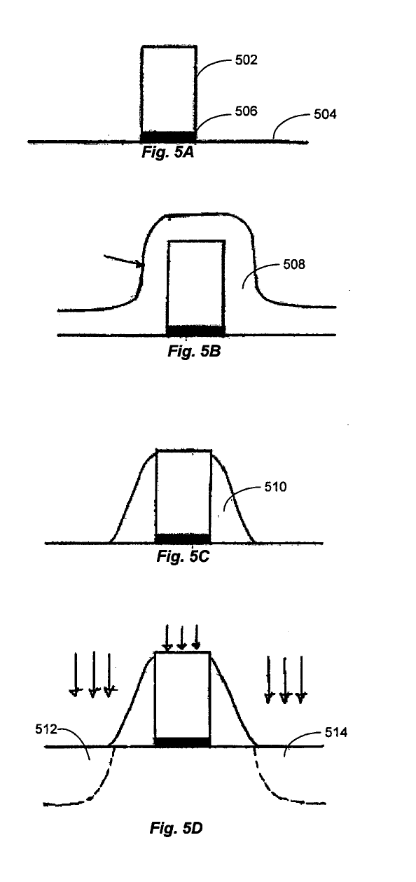

FIGS. 5A-E show cross-sectional views of steps in forming source-drain regions in a transistor with the aid of a disposable sidewall spacer according to embodiments of the invention. FIG. 5A shows components of a transistor formed on a portion of a silicon substrate wafer 504. The transistor components may include a gate electrode 502 that is attached to the substrate 504 through a gate oxide layer 506. The substrate wafer 504 may be provided to a processing chamber (not shown) where an amorphous carbon film 508 may be formed over the components. As noted above, the amorphous carbon film 508 may be formed by plasma deposition (e.g., continuous or pulsed plasma deposition) of a precursor mixture of a hydrocarbon compound and, in some instances, an inert gas such as argon (Ar) or helium (He). Examples of the film 508 may include the amorphous carbon found in the Advanced Patterning Film™ (“APF”) from Applied Materials of Santa Clara, Calif. The film 508 may have a thickness of about 300 Å or more, and may have a side-to-top conformality ratio of about 70% or more.

As shown in FIG. 5C, the film 508 may be etched by conventional etching techniques to form sacrificial sidewall spacers 510 that shield the sidewall surfaces of the gate electrode 502 from subsequent dopant implant steps. FIG. 5D shows one of those implant steps where the source and drain regions 512 and 514 are formed in the substrate 504 adjacent to the sacrificial spacers 510, by for example, deep ion implantation of the dopants into the substrate (e.g., bombarding the substrate with boron ions having an energy of about 3 keV at a density of about 1×10¹⁶ ions/cm²). Following the formation of the source and drain regions 512 and 514, the sacrificial sidewall spacers 510 may be removed, as shown in FIG. 5E. Removal of the spacers 510 may be performed by a stripping process, and/or an oxidizing plasma (e.g., O₂ and/or O₃ plasma) ashing process to remove amorphous carbon materials as described above.

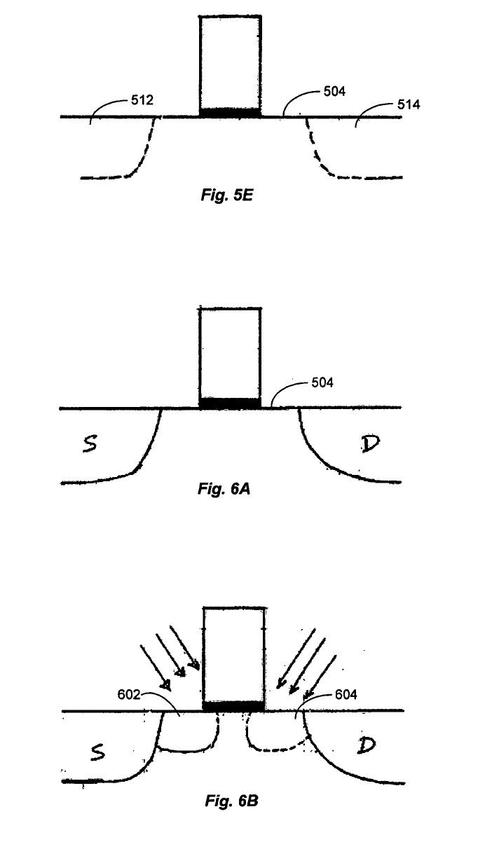

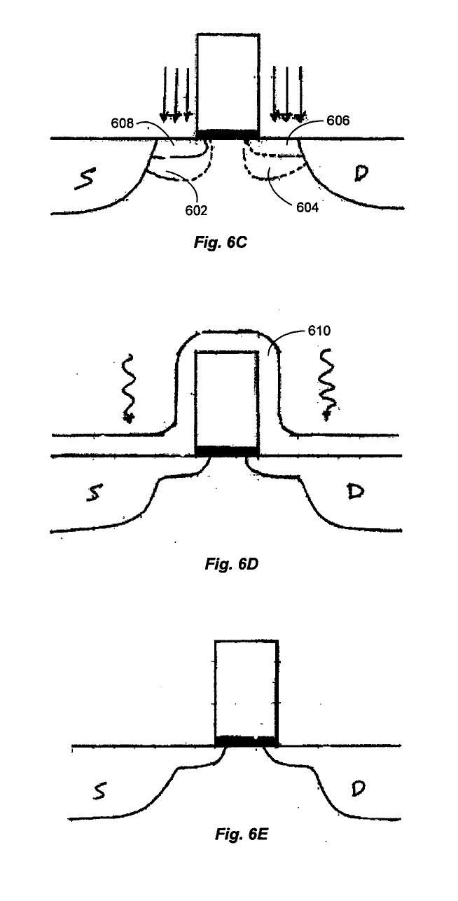

Referring now to FIGS. 6A-E cross-sectional views of steps in forming implant regions in a transistor according to embodiments of the invention are shown. FIG. 6A shows the a spike anneal being performed on the source and drain regions 512 and 514, to activate the dopants in these regions. In the spike anneal, temperatures in the source and drain regions of the substrate 504 may be rapidly raised to 1000° C. or more (e.g., 1050° C.) to activate the dopants. FIG. 6B shows halo implant regions 602 and 604 being implanted adjacent to the source and drain regions 512 and 514, and the gate electrode 502 in the substrate 504. Halo implant formation may include, for example, bombardment of the implant region with boron ions having an energy of about 5 keV at a density of about 2×10¹⁴ ions/cm². Additional source and drain extension implants 606 and 608 may also be implanted in the substrate 504, as shown in FIG. 6C. Formation of the extension implants 606 and 608 may be done, for example, by boron ion bombardment, where the boron ions have an average energy of about 0.5 keV and a density of about 2×10¹⁵ ions/cm². Embodiments also include the formation of pre-amorphization implants (not shown) in the substrate, which may be done, for example, by bombarding the implant region with germanium ions with an average energy of about 5 keV, and an average density of about 1×10¹⁵ ions/cm².

Following the formation of the halo implant regions 602 and 604, and source/drain extension implants 606 and 608, another anneal may be performed to activate the dopants in these regions (and further activate the dopants in the source and drain regions). As shown in FIG. 6D, a layer 610 of absorptive material 610 is formed over the transistor components in preparation for a laser anneal. The absorptive material may be made from, for example, the Advanced Patterning Film™ (“APF”) from Applied Materials of Santa Clara, Calif., and may have a thickness of, for example, about 500 Å or more. Following the deposition, laser light of the appropriate wavelength may be absorbed by the absorptive layer 610 where at least a portion of the laser light energy is converted into heat to anneal the underlying halo implant regions 602 and 604, source/drain extension implants 606 and 608, and source and drain regions 512 and 514. This laser anneal process may be, for example, a dynamic surface anneal (DSA) millisecond laser anneal developed by Applied Materials. Other light anneal processes that may be used include a flash anneal. At the end of the anneal, the absorptive layer 610 may be removed by conventional stripping and/or ashing processes, to form the exposed gate electrode side surfaces shown in FIG. 6E.

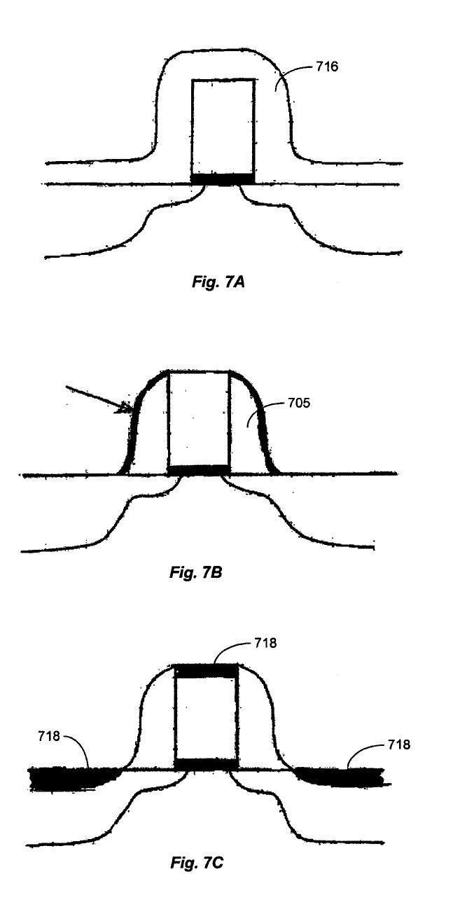

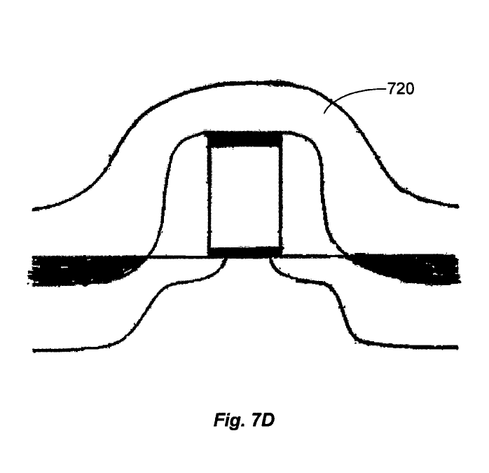

FIGS. 7A-D show cross-sectional views of steps in forming sidewall spacers 705 and silicide layers 718 in a transistor according to embodiments of the invention. FIG. 7A shows transistor components that include a gate oxide layer 506 sandwiched between the gate electrode 502 and substrate 504. The source region 512 and drain region 514, along with the adjacent halo regions 602 and 604 have been formed in the substrate 504, as described in FIGS. 6A-E above. A low-k spacer layer 716 is formed over the transistor components via a pulsed plasma deposition process. The layer 716 may have a thickness of about 300 Å, and a side-to-top conformality ratio of about 70% or more.

The low-k spacer layer 716 may be a silicon, oxygen, and carbon containing layer (e.g., a silicon oxycarbide layer) deposited at temperatures of about 500° C. or less. A silicon oxycarbide layer may contain about 15 atomic % or more of oxygen. The layer may also contain hydrogen, nitrogen, or combinations thereof. The layer may be generated from organosilicon precursor compounds that may be used to generate a plasma that is deposited on the transistor surface and forms a dielectric layer having a dielectric constant (k) of about 3.5 or less (e.g., a k value of about 3).

The organosilicon precursor compounds may include aliphatic organosilicons, cyclic organosilicons, and combinations of aliphatic and cyclic organosilicons. Cyclic organosilicons typically have a ring with three or more silicon atoms, and which also may have one or more oxygen atoms. Commercially available cyclic organosilicon compounds include rings having alternating silicon and oxygen atoms with one or two alky groups bonded to the silicon atoms.

Alphatic organosilicon compounds have linear or branched molecular chains that include one or more silicon atom, and one or more carbon atom, and the chain may also include one or more oxygen atom. Commercially available aliphatic organosilicon compounds include organosilanes that do not contain oxygen between silicon atoms, and organosiloxanes that contain oxygen between two or more silicon atoms.

The carbon content of the deposited layers refers to atomic analysis of the layer structure that typically does not contain significant amounts of non-bonded hydrocarbons. The carbon contents are represented by the percent of carbon atoms in the deposited layer, excluding hydrogen atoms that are difficult to quantify. For example, a layer having an average of one silicon atom, one oxygen atom, one carbon atom, and two hydrogen atoms has a carbon content of 20 atomic percent (one carbon atom per five total atoms), or a content of 33 atomic percent excluding hydrogen atoms (one carbon per three total atoms). Tables 1 and 2 below lists some specific examples of cyclic and alphatic organosilicon compounds that may be used in a precursor mixture to form the low-k spacer. The compounds listed in the tables are illustrative, and do not represent all the compounds that may be used to form the low-k spacer layer.

TABLE 1
Examples of Cycle Organosilicon Compounds

| Chemical Name | Structural Information |
|---|---|
| 1,3,5-trisilano-2,4,6- | —(—SiH₂CH₂—)₃— (cyclic) |
| trimethylene | |
| 1,3,5,7- | —(—SiHCH₃—O—)₄— (cyclic) |
| tetramethylcyclotetrasiloxane | |
| (TMCTS) | |
| Octamethylcyclotetrasiloxane | —(—Si(CH₃)₂—O—)₄— (cyclic) |
| (OMCTS) | |
| 2,4,6,8,10- | —(—SiHCH₃—O—)₅— (cyclic) |
| pentamethylcyclopentasiloxane | |
| 1,3,5,7-tetrasilano-2,6- | —(—SiH₂—CH₂—SiH₂—O—)₂— |
| dioxy-4,8-dimethylene | (cyclic) |
| Hexamethylcyclotrisiloxane | —(—Si(CH₃)₂—O—)₃— (cyclic) |

TABLE 2
Examples of Aliphatic Organosilicon Compounds

| Chemical Name | Structural Information |
|---|---|
| Methylsilane | CH₃—SiH₃ |
| Dimethylsilane | (CH₃)₂—SiH₂ |
| Trimethylsilane | (CH3)₃—SiH |
| Dimethyldimethoxysilane | (CH₃)₂—Si—(OCH₃)₂ |
| 1,3-dimethyldisiloxane | CH₃—SiH₂—O—SiH₂—CH₃ |
| 1,1,3,3-tetramethyldisiloxane | (CH₃)₂—SiH—O—SiH—(CH₃)₂ |
| bis(1-methyldisiloxanyl)methane | (CH₃—SiH₂—O—SiH₂—)₂—CH₂ |

The organosilicon compounds may be reacted in plasma comprising a relatively inert gas, such as nitrogen (N₂) and/or noble gases like argon, or helium. For example, a Si—O—C low-k spacer layer may be formed from a precursor mixture of OMCTS and helium. Embodiments also include forming the low-k spacer from precursor mixtures of separate carbon, silicon and oxygen compounds, such as hydrocarbon, silane, and oxygen (O₂, O₃). Embodiments may also include precursor mixtures having an organosilicon compound (or compounds) and an oxidizer (e.g., CO, CO₂, O₂, O₃, etc.).

Referring now to FIG. 7B, the spacer layer 716 formed on the gate electrode 502 and substrate 504 may be etched by a conventional etch process and surface treatment (e.g., CMP) to remove spacer film from the top of the gate electrode 502 and at least a portion of the source and drain regions 512 and 514, forming spacers 705. Embodiments also include a surface treatment that may be performed to seal pores in the spacers 705 to prevent the diffusion of dopants and metals through the spacers. For example, a 30 Å to 50 Å thick film of silicon oxide (SiO₂) may be formed on the surface of the spacers 705 by PECVD. Embodiments still also include forming a similar sealing film of SiO₂ (e.g., about 30 Å to about 50 Å thick) on the sidewall surfaces of the gate electrode 502 before forming the spacer layer 716.

Following the removal of excess spacer layer material, silicide layers 718 may be formed on the gate electrode 502, and source/drain regions 512 and 514, as shown in FIG. 7C. The silicide layers 718 are conductive, and may be alloys of metal (e.g. Ni—Si) and silicon formed from the reaction of a metal layer with the underlying source-drain regions and gate electrode. For example, the silicide layers 718 may be formed by depositing a nickel film (not shown) which reacts with the exposed silicon to form Ni—Si regions. The unreacted portions of the Ni film may be etched away, leaving the reacted Ni—Si regions as silicide layers 718. In post-silicidation steps, electrical contacts may be formed on silicide layers 718 to conduct electrical signals to and from the transistor.

FIG. 7D shows a tensile layer 720 formed over the previously formed layers of the transistor. As noted above, the tensile layer 720 may be added to change or magnify the stress level in the channel region of the transistor to promote faster channel conductance. In some instances, the tensile layer 720 may act as a contact-etch stop layer. Strain exerted on the components of the transistor by the tensile layer 720 may be tuned from tensile to compressive. When the tensile layer 720 exerts tensile stress on the transistor, the underlying layers may become compressive, and the channel region may become tensile.

The tensile layer 720 may be a silicon nitride layer (e.g. Si₃N₄), and may be formed at temperatures around 400° C. by combining silicon sources and NH₃ to deposit a conformal nitride layer. Embodiments also include the use of hydrogen (H₂) in the formation of the tensile layer 720. The hydrogen facilitates the formation of N—H and Si—H bonds, in addition to the dominant Si—N bonds. While not intending to be held to a particular theory, it is believed that increasing the number of Si—H bonds in the nitride layer weakens the strength of the Si—N bonds attached to the same Si atom, which (on a macro scale) stretches the nitride film to make it more tensile.

It should be appreciated that numerous variations can exist for steps in the processes shown and described in FIGS. 5-7. For example, the halo regions 602 and 604, and/or extension implant regions 606 and 608, may be formed before the sacrificial spacers 510 are removed and the source and drain regions 512 and 514 are first annealed. The soak, spike, and laser anneals described may be substituted for other annealing techniques, or substituted for each other. Numerous other variations are also contemplated as embodiments of the invention.

Exemplary Process Chambers

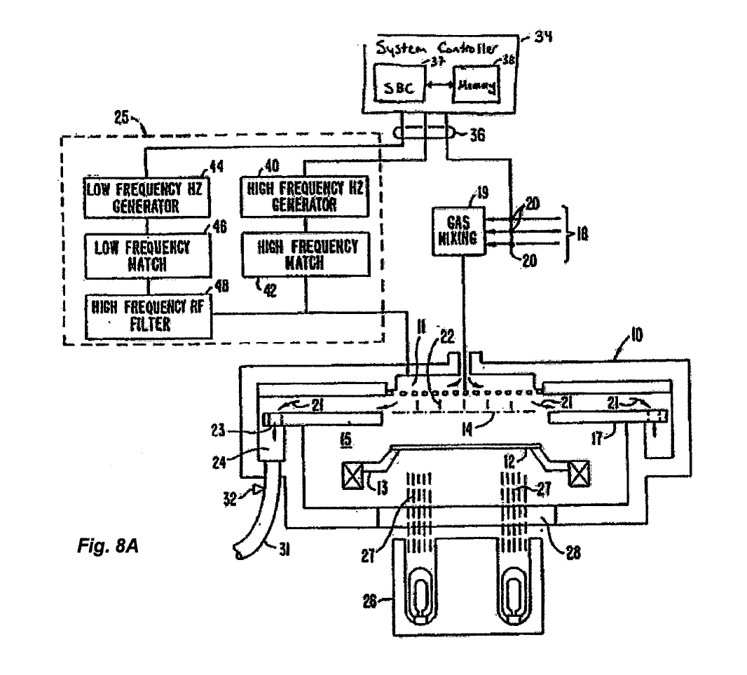

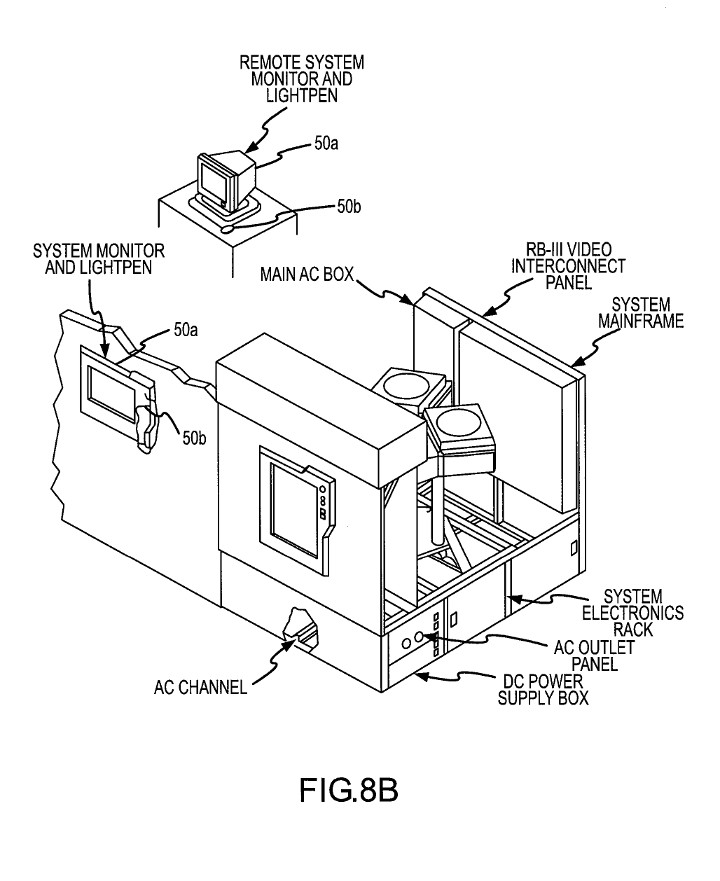

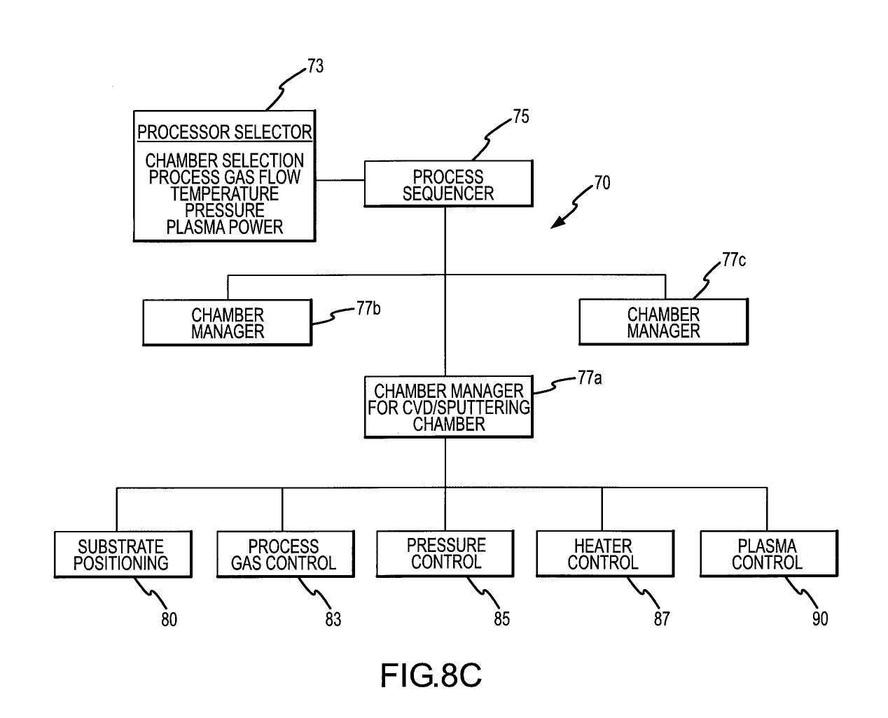

FIG. 8A illustrates an embodiment of a plasma enhanced chemical vapor deposition (PECVD) system 10 that may be used in conjunction with embodiments of the methods of the present invention. System 10 includes a vacuum chamber 15 in which one or more layers may be deposited on a substrate (not shown). System 10 contains a gas distribution manifold 11 for dispersing process gases through perforated holes in manifold 11 to a substrate (e.g., a 200 mm wafer, 300 mm wafer, etc.) positioned on susceptor 12. Susceptor 12 is thermally responsive and is mounted on supports 13 such that the susceptor 12 (and the substrate) can be controllably moved between a lower loading/off-loading position and an upper processing position 14, which is in proximity to manifold 11. A center board (not shown) includes sensors for providing information on the position of the substrate.

When susceptor 12 and substrate are in processing position 14, they are surrounded by baffle plate 17 having a plurality of spaced holes 23 which exhaust into an annular vacuum manifold 24. Deposition and carrier gases are supplied through supply lines 18 into a mixing system 19 where they are combined and then sent to manifold 11. Supply lines 18 for each of the process gases may include (i) safety shut-off valves (not shown) that can be used to automatically or manually shut-off the flow of process gas into the chamber, and (ii) mass flow controllers 20 that measure the flow of gas or liquid through the supply lines. When toxic gases are used in the process, the several safety shut-off valves may be positioned on each gas supply line in conventional configurations.

The rate at which deposition and carrier gases are supplied to gas mixing system 19 is controlled by liquid or gas mass flow controllers 20 and/or by valves. During processing, gas supplied to manifold 11 is vented toward and uniformly distributed radially across the surface of the wafer in a laminar flow as indicated by arrows 21. An exhaust system then exhausts the gas via ports 23 into the circular vacuum manifold 24 and out an exhaust line 31 by a vacuum pump system (not shown). The rate at which gases are released through exhaust line 31 is controlled by a throttle valve 32.

When performing a plasma enhanced process in system 10, a controlled plasma may be formed adjacent to the substrate by RF energy applied to manifold 11 from RF power supply 25. Manifold 11 may also act as an RF electrode, while susceptor 12 is grounded. RF power supply 25 may supply single or mixed frequency RF power (or other desired variations) to manifold 11 to enhance the decomposition of reactive species introduced into chamber 15. The mixed frequency RF power is generated by a high frequency RF generator 40 (RF1) and corresponding match circuit 42 and a low frequency RF generator 44 (RF2) and corresponding match circuit 46. A high frequency filter 48 prevents voltage generated by high frequency generator 40 from damaging the low frequency generator. During the formation of the sacrificial spacers, and/or low-k sidewall spacers, the low frequency RF generator 44 (RF2) may be used exclusively to supply LF-RF power to the plasma.

Heat is distributed by an external lamp module 26. External lamp heater module 26 provides a collimated annular pattern of light 27 through a quartz window 28 onto an annular outer peripheral portion of susceptor 12. Such heat distribution compensates for the natural heat loss pattern of susceptor 12 and provides rapid thermal and uniform susceptor and substrate heating for effecting deposition.

The chamber lining, gas distribution manifold faceplate, supports 13, and other system hardware may be made out of materials such as aluminum or anodized aluminum. An example of such an apparatus is described in U.S. Pat. No. 5,000,113 entitled “Thermal CVD/PECVD Reactor and Use for Thermal Chemical Vapor Deposition of Silicon Dioxide and In situ Multi-step Planarized Process,” issued to Wang et al, an assigned to Applied Materials, Inc., the assignee of the present invention, the entire contents of which is herein incorporated by reference.

A motor (not shown) raises and lower susceptor 12 between a processing position 14 and a lower, substrate-loading position. Motors and optical sensors are used to move and determine the position of movable mechanical assemblies such as throttle valve 32 and susceptor 12. The heater, motors, valves and flow controllers 20 connected to supply lines 18, gas delivery system, throttle valve 32, RF power supply 25, and lamp magnet drivers are all controlled by a system controller 34 over control lines 36, some of which are shown in FIG. 3A.

System controller 34 controls activities of the apparatus. The system controller executes system control software, which is a computer program stored in a computer-readable medium such as a memory 38. Preferably, memory 38 may be a hard disk drive, but memory 38 may also be other kinds of memory. The computer program includes sets of instructions that dictate, for example, the timing, mixture of gases, chamber pressure, chamber temperature, RF power levels, susceptor position, and other parameters of a process. Other computer programs (e.g., one stored on another memory device such as a floppy disk or other program storage media) may also be used to operate processor 34. For example, system controller 34 may be used to execute a computer program stored in memory 38 to generate a pulsed-plasma during the formation of the sacrificial and/or low-k spacer layers.

The system controller may include a hard disk drive (memory 38), floppy disk drive and card rack, among other elements. The card rack contains a single board computer (SBC) processor 37, analog and digital input/output boards, interface boards and stepper motor controller boards. Various parts of system 10 may conform to the Versa Modular European (VME) standard that defies board, card cage, and connector dimensions and types. The VME standard also defines the bus structure having a 16-bit data bus and 24-bit address bus.

Referring now to FIG. 8B, a substrate processing apparatus including PECVD system 10 is shown. The apparatus also shows the interface between a user and processor via a monitor 50a and light pen 50b. In other embodiments, two monitors may be used, where a first monitor is located in a clean room (not shown) for apparatus operators, and a second monitor is located outside the clean room for viewing by service technicians. Both monitors may display the information.

Light pen 50b detects light emitted by monitor 50a with a light sensor in the tip of the pen. To select a particular screen or function, the operator touches a designated area of the display screen and pushes the button on pen 50b. The touched area changes its highlighted color, or a new menu or screen is displayed, confirming communication between the light pen and the display screen. Other devices (e.g., keyboard, mouse, etc.) may be used instead of (or in addition to) light pen 50b to allow the user to communicate with processor 34.

The process for depositing the film can be implemented using a computer program product that is executed by processor 34. The computer program code can be written in any conventional computer readable programming language, such as, 68000 assembly language, C, C++, Pascal, Java, Fortran, or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled windows library routines. To execute the linked compiled object code, the system user invokes the object code, causing the computer system to load the code in memory, from which the CPU reads and executes the code to perform the tasks identified in the program.

FIG. 8C shows an illustrative block diagram of the hierarchical control structure of the system control software (e.g., computer program 70) according to embodiments of the apparatus. A user may enter a process set number and process chamber number into a process selector subroutine 73 in response to menus or screens displayed on the CRT monitor by using an interface (e.g., light pen 50b). The process sets are predetermined sets of process parameters necessary to carry out specified processes, and are identified by predefined set numbers. The process selector subroutine 73 may identify (i) the desired process chamber, and (ii) the desired set of process parameters needed to operate the process chamber for performing the desired process. The process parameters for performing a specific process relate to process conditions such as, for example, process gas composition and flow rates, temperature, pressure, plasma conditions (e.g., RF power levels, low frequency RF, etc.) cooling gas pressure, and chamber wall temperature, among others. They may be provided to the user in the form of a recipe. The parameters specified by the process recipe may be entered utilizing the light pen/monitor interface (50a-b).

Signals for monitoring the process are provided by the analog input and digital input boards of the system controller and the signals for controlling the process are output on the analog output and digital output boards of system 10.

A process sequencer subroutine 75 comprises program code that may accept the identified process chamber and set of process parameters from the process selector subroutine 73, and control operation of the various process chambers. Multiple users can enter process set numbers and process chamber numbers, or a user can enter multiple process set numbers and process chamber numbers, so the sequencer subroutine 75 operates to schedule the selected processes in the desired sequence. Preferably the sequencer subroutine 75 includes a program code to perform the steps of (i) monitoring the operation of the process chambers to determine if the chambers are being used, (ii) determining what processes are being carried out in the chambers being used, and (iii) executing the desired process based on availability of a process chamber and type of process to be carried out. Conventional methods of monitoring the process chambers can be used, such as polling. When scheduling which process is to be executed, the sequencer subroutine 75 can be designed to take into consideration the present condition of the process chamber being used in comparison with the desired process conditions for a selected process, or the “age” of each particular user entered request, or any other relevant factor a system programmer desires to include for determining scheduling priorities.

Once the sequencer subroutine 75 determines which process chamber and process set combination is going to be executed next, the sequencer subroutine 75 causes execution of the process set by passing the particular process set parameters to a chamber manager subroutine 77a-c which controls multiple processing tasks in a process chamber 15 according to the process set determined by the sequencer subroutine 75. For example, the chamber manager subroutine 77a comprises program code for controlling sputtering and CVD process operations in the process chamber 15. The chamber manager subroutine 77 also controls execution of various chamber component subroutines which control operation of the chamber components necessary to carry out the selected process set. Examples of chamber component subroutines are substrate positioning subroutine 80, process gas control subroutine 83, pressure control subroutine 85, heater control subroutine 87, and plasma control subroutine 90. Those having ordinary skill in the art would readily recognize that other chamber control subroutines can be included depending on what processes are desired to be performed in the process chamber 15. In operation, the chamber manager subroutine 77a selectively schedules or calls the process component subroutines in accordance with the particular process set being executed. The chamber manager subroutine 77a schedules the process component subroutines similarly to how the sequencer subroutine 75 schedules which process chamber 15 and process set is to be executed next. Typically, the chamber manager subroutine 77a includes steps of monitoring the various chamber components, determining which components needs to be operated based on the process parameters for the process set to be executed, and causing execution of a chamber component subroutine responsive to the monitoring and determining steps.

Operation of particular chamber component subroutines will now be described with reference to FIGS. 8A-C. The substrate positioning subroutine 80 comprises program code for controlling chamber components that are used to load the substrate onto the susceptor 12, and optionally to lift the substrate to a desired height in the chamber 15 to control the spacing between the substrate and the gas distribution manifold 11. When a substrate is loaded into the process chamber 15, the susceptor 12 is lowered to receive the substrate, and thereafter, the susceptor 12 is raised to the desired height in the chamber, to maintain the substrate at a first distance or spacing from the gas distribution manifold during the CVD process. In operation, the substrate positioning subroutine 80 controls movement of the susceptor in response to process set parameters related to the support height that are transferred from the chamber manager subroutine 77a.

The process gas control subroutine 83 has program code for controlling process gas composition and flow rates. The process gas control subroutine 83 controls the open/close position of the safety shut-off valves, and also ramps up/down the mass flow controllers to obtain the desired gas flow rate. The process gas control subroutine 83 is invoked by the chamber manager subroutine 77a, as are all chamber component subroutines, and receives from the chamber manager subroutine process parameters related to the desired gas flow rates. Typically, the process gas control subroutine 83 operates by opening the gas supply lines, and repeatedly (i) reading the necessary mass flow controllers, (ii) comparing the readings to the desired flow rates received from the chamber manager subroutine 77a, and (iii) adjusting the flow rates of the gas supply lines as necessary. Furthermore, the process gas control subroutine 83 includes steps for monitoring the gas flow rates for unsafe rates, and activating the safety shut-off valves when an unsafe condition is detected.

In some processes, an inert gas such as argon is flowed into the chamber 15 to stabilize the pressure in the chamber before reactive process gases are introduced into the chamber. For these processes, the process gas control subroutine 83 is programmed to include steps for flowing the inert gas into the chamber 15 for an amount of time necessary to stabilize the pressure in the chamber, and then the steps described above would be carried out. Additionally, when a process gas is to be vaporized from a liquid precursor, for example octamethylcyclotetrasiloxane (OMCTS), the process gas control subroutine 83 would be written to include steps for bubbling a delivery gas such as helium through the liquid precursor in a bubbler assembly or introducing a carrier gas such as helium to a liquid injection system. When a bubbler is used for this type of process, the process gas control subroutine 83 regulates the flow of the delivery gas, the pressure in the bubbler, and the bubbler temperature in order to obtain the desired process gas flow rates. As discussed above, the desired process gas flow rates are transferred to the process gas control subroutine 83 as process parameters. Furthermore, the process gas control subroutine 83 includes steps for obtaining the necessary delivery gas flow rate, bubbler pressure, and bubbler temperature for the desired process gas flow rate by accessing a stored table containing the necessary values for a given process gas flow rate. Once the necessary values are obtained, the delivery gas flow rate, bubbler pressure and bubbler temperature are monitored, compared to the necessary values and adjusted accordingly.

The pressure control subroutine 85 comprises program code for controlling the pressure in the chamber 15 by regulating the size of the opening of the throttle valve in the exhaust system 115 of the chamber. The size of the opening of the throttle valve is set to control the chamber pressure to the desired level in relation to the total process gas flow, size of the process chamber, and pumping setpoint pressure for the exhaust system 115. When the pressure control subroutine 85 is invoked, the desired, or target, pressure level is received as a parameter from the chamber manager subroutine 77a. The pressure control subroutine 147 operates to measure the pressure in the chamber 15 by reading one or more conventional pressure manometers connected to the chamber, compare the measure value(s) to the target pressure, obtain PID (proportional, integral, and differential) values from a stored pressure table corresponding to the target pressure, and adjust the throttle valve according to the PID values obtained from the pressure table. Alternatively, the pressure control subroutine 85 can be written to open or close the throttle valve to a particular opening size to regulate the chamber 15 to the desired pressure.

The heater control subroutine 87 comprises program code for controlling the temperature of the lamp module that is used to heat the substrate 20. The heater control subroutine 87 is also invoked by the chamber manager subroutine 77a and receives a target, or setpoint, temperature parameter. The heater control subroutine 87 measures the temperature by measuring voltage output of a thermocouple located in a susceptor 12, compares the measured temperature to the setpoint temperature, and increases or decreases current applied to the lamp module 26 to obtain the setpoint temperature. The temperature is obtained from the measured voltage by looking up the corresponding temperature in a stored conversion table, or by calculating the temperature using a fourth order polynomial. When radiant lamps are used to heat the susceptor 12, the heater control subroutine 87 gradually controls a ramp up/down of current applied to the lamp. The gradual ramp up/down increases the life and reliability of the lamp. Additionally, a built-in fail-safe mode can be included to detect process safety compliance, and can shut down operation of the lamp module 26 if the process chamber 15 is not properly set up.

The plasma control subroutine 90 comprises program code for setting low and high frequency the RF power levels applied to the process electrodes in the chamber 15, and to set the low frequency RF frequency employed. Similar to the previously described chamber component subroutines, the plasma control subroutine 90 is invoked by the chamber manager subroutine 77a.

The above reactor description is mainly for illustrative purposes an variations in components such as susceptor design, heater design, RF power frequencies, location of RF power connections and others are possible. For example, the substrate could be supported and heated by a resistively heated platen. The methods of the present invention are not limited to a specific PECVD apparatus like the one shown.

Having described several embodiments, it will be recognized by those of skill in the art that various modifications, alternative constructions, and equivalents may be used without departing from the spirit of the invention. Additionally, a number of well known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the electrode” includes reference to one or more electrodes and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of forming source and drain regions in a semiconductor transistor, the method comprising:
forming a first sidewall spacer on sidewall surfaces of a gate electrode that is formed on an underlying substrate, wherein the first sidewall spacer comprises amorphous carbon;
implanting the source and drain regions in the semiconductor substrate, and removing the first sidewall spacer before annealing the source and drain regions; and
forming a second sidewall spacer on the sidewall surfaces of the gate electrode, wherein the second sidewall spacer has a k-value less than 4.

2. The method of claim 1, wherein the first sidewall spacer is removed by ash etching the spacer with an oxidizer.

3. The method of claim 2, wherein the oxidizer is oxygen or ozone.

4. The method of claim 1, wherein the annealing of the source and drain regions is done by spike annealing.

5. The method of claim 1, wherein the annealing of the source and drain region is done by soak annealing.

6. The method of claim 1, wherein the method further comprises forming implant regions in the semiconductor substrate adjacent to the source and drain regions.

7. The method of claim 6, wherein the implant regions are annealed before the second sidewall spacer is formed.

8. The method of claim 7, wherein the annealing of the implant regions is done by laser annealing.

9. The method of claim 1, wherein the method comprises forming a silicide layer on a top surface of the gate electrode after the forming of the second sidewall spacer.

10. The method of claim 1, wherein the second sidewall spacer comprises carbon-doped silicon oxide.

11. The method of claim 1, wherein the second sidewall spacer is formed by plasma deposition of one or more precursors comprising silicon, carbon, and oxygen.

12. The method of claim 11, wherein the one or more precursors comprise octamethylcyclotetrasiloxane.

13. The method of claim 11, wherein the one or more precursors are selected from the group consisting of trimethylsilane, tetramethylsilane, tetraethoxysilane, oxygen, ozone, and carbon dioxide.

14. A method of forming implant regions in a semiconductor transistor, the method comprising:
forming source and drain regions adjacent to a gate electrode in a semiconductor substrate;
removing a first sidewall spacer from the gate electrode before annealing the source and drain regions, wherein the first sidewall spacer comprises amorphous carbon;
forming the implant regions in the semiconductor substrate; and
forming a second sidewall spacer on sidewall surfaces of the gate electrode.

15. The method of claim 14, wherein the removal of the first sidewall spacer comprises ash etching the spacer material with an oxygen-ozone plasma.

16. The method of claim 14, wherein the annealing of the source and drain regions includes heating the semiconductor substrate to about 1000° C. or more.

17. The method of claim 14, wherein the method further comprising depositing a silicon oxide film on the second sidewall spacer to seal pores in the spacer.

18. The method of claim 14, wherein the method further comprises depositing a tensile film on the semiconductor transistor after the formation of the second sidewall spacer.

19. A method of forming a semiconductor transistor, the method comprising:
forming a gate electrode on a semiconductor substrate;
forming a temporary sidewall spacer on sidewall surfaces of the gate electrode, wherein the temporary sidewall spacer comprises amorphous carbon;
implanting source and drain regions in the semiconductor substrate, and removing the temporary sidewall spacer before annealing the source and drain regions;
forming a permanent low-k sidewall spacer on the sidewall surfaces of the gate electrode, wherein the low-k sidewall spacer comprises carbon-doped silicon oxide.

20. The method of claim 19, wherein the temporary sidewall spacer is formed from a decomposition of a mixture comprising a hydrocarbon gas and an inert gas.

21. The method of claim 20, wherein the decomposition of the mixture comprises a plasma enhanced thermal decomposition.

22. A method of forming a sidewall spacer, the method comprising:
generating a plasma from one or more precursors comprising silicon, carbon, and oxygen, wherein the plasma is generated using radio-frequency power;
depositing the plasma on sidewall surfaces of a gate electrode to form a first portion of the sidewall spacer;
pausing the deposition of the plasma on the sidewall surfaces of the gate electrode; and
resuming the deposition of the plasma to form a second portion of the sidewall spacer.

23. The method of claim 22, wherein the radio-frequency power comprises a high frequency and low frequency RF power.

24. The method of claim 23, wherein the low-frequency radio-frequency power has a frequency of about 300 kHz to about 400 kHz.

25. The method of claim 24, wherein the low-frequency radio-frequency power comprises a frequency of about 350 kHz.

26. The method of claim 23, wherein the high-frequency radio-frequency power has a power level of about 250 Watts, and the low-frequency radio-frequency power has a power level of about 50 Watts for a 200 mm wafer deposition.

27. The method of claim 22, wherein the plasma to form the first portion of the sidewall spacer is deposited for about 1 second.

28. The method of claim 22, wherein plasma to form the first portion of the sidewall spacer is deposited for less than 2 seconds.

29. The method of claim 22, wherein plasma to form the first portion of the sidewall spacer is deposited for less than 1.5 seconds.

30. The method of claim 22, wherein the first portion of the sidewall spacer has a thickness of about 10 Å to about 50 Å.

31. The method of claim 22, wherein the pause in the deposition of the plasma is about 5 seconds, and the resumption of the deposition of the plasma occurs for about 1 second before another pause in the deposition.

32. The method of claim 22, wherein the second portion of the sidewall spacer has a thickness of about 10 Å to about 50 Å.

33. The method of claim 22, wherein the sidewall spacer has a total thickness of about 500 Å to about 1000 Å.

34. The method of claim 22, wherein the one or more precursors comprises octamethylcyclotetrasiloxane.

35. The method of claim 22, wherein the one or more precursors is selected from the group consisting of trimethylsilane, tetramethylsilane, tetraethoxysilane, oxygen, ozone, and carbon dioxide, and an inert gas.

36. The method of claim 35, wherein the inert gas comprises helium.

37. A method to enhance conformality of a sidewall spacer layer formed on a gate electrode, the method comprising:
pulsing a radio-frequency power source to generate periodically a plasma from one or more precursors comprising silicon, carbon, and oxygen; and
depositing the plasma on sidewall surfaces of a gate electrode to form the sidewall spacer layer.

38. The method of claim 37, wherein the plasma is generated during about 16% to about 20% of a total time for a pulse cycle.

39. The method of claim 37, wherein the plasma is generated for about 1 second of a 6 second pulse cycle.

40. The method of claim 37, wherein the conformality of the sidewall spacer layer is about 60% or more.

41. The method of claim 37, wherein the conformality of the sidewall spacer layer is about 70% or more.

42. The method of claim 37, wherein the radio-frequency power source generates low-frequency radio-frequency power to generate the plasma.

43. A method of forming a conformal layer on a gate electrode, the method comprising:
generating a plasma from one or more precursors comprising silicon, carbon, and oxygen, wherein the plasma is generated with radio-frequency power comprising low-frequency radio-frequency power; and
depositing the plasma on sidewall surfaces of a gate electrode to form the conformal layer.

44. The method of claim 43, wherein the low-frequency radio-frequency power comprises a frequency of about 300 kHz to about 400 kHz.

45. The method of claim 43, wherein the plasma is generated periodically by pulsing the radio-frequency power at a duty cycle of about 16% to about 20%.
